(19) United States
(12) Patent Application Publication
(10) Pub. No.: US 2017/0174894 A1
(43) Pub. Date: Jun. 22, 2017

(54) STRESS TOLERANT COMPOSITE MATERIAL AND ARCHITECTURE

(71) Applicants: Sri Chaitra Chavali, Chandler, AZ (US); Siddharth Alur, Chandler, AZ (US); Amanda E. Schuckman, Scottsdale, AZ (US)

(72) Inventors: Sri Chaitra Chavali, Chandler, AZ (US); Siddharth Alur, Chandler, AZ (US); Amanda E. Schuckman, Scottsdale, AZ (US)

(21) Appl. No.: 14/973,116

(22) Filed: Dec. 17, 2015

(51) Int. Cl. C09C 1/00; H01L 23/29; H01L 23/532; C08K 9/02

(52) U.S. Cl. CPC C09C 1/0081; C08K 9/02; H01L 23/295; H01L 23/5329

(57) ABSTRACT

This document discusses, among other things, a stress-tolerant composite microelectronic material comprising a composite nanofiller including a nanofiller core material having a modulus greater than a core material composed of silicon dioxide (SiO2) alone, and an outer layer of oxidized nanofiller core material surrounding the nanofiller core material.

### TECHNICAL FIELD

This document relates generally to composite semiconductor material and more particularly to stress tolerant composite semiconductor material and architecture.

### BACKGROUND

Polymeric materials have various uses in the semiconductor technologies, including as adhesives, encapsulates, packaging, substrates, or fill. Stiffness and warpage due to thermal considerations is a challenge in the microelectronics industry that arises due to mismatch in coefficient of thermal expansion (CTE) between interacting components, such as a die and a substrate, a copper layer and a polymer, etc.

Polymer and dielectric materials used in microelectronic substrates and assemblies generally include resin, filler, and reinforcement fibers. The mechanical properties of existing polymeric materials is not sufficient to overcome thermal stress driven CTE mismatch.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an existing silicon dioxide (SiO2) filler material.

FIG. 2 illustrates generally an example modified filler material.

FIG. 3 illustrates generally a conventional substrate architecture.

FIG. 4 illustrates generally a cross section of an example hybrid architecture.

FIGS. 5-11 illustrate generally example cross sections of a process flow for a hybrid architecture.

### DETAILED DESCRIPTION

The present inventors have recognized, among other things, a modified filler material having a higher modulus (e.g., ˜2-6 times higher) than conventional filler material without compromising bonding between the filler material and the polymer resin, mitigating separation, adhesion, warpage, and other reliability risks.

Conventional filler material can include silicon dioxide (SiO2), magnesium peroxide (MgO2), aluminum oxide (Al2O3), calcium carbonate (CaCO3), or clays, typically on the order of microns to submicrons.

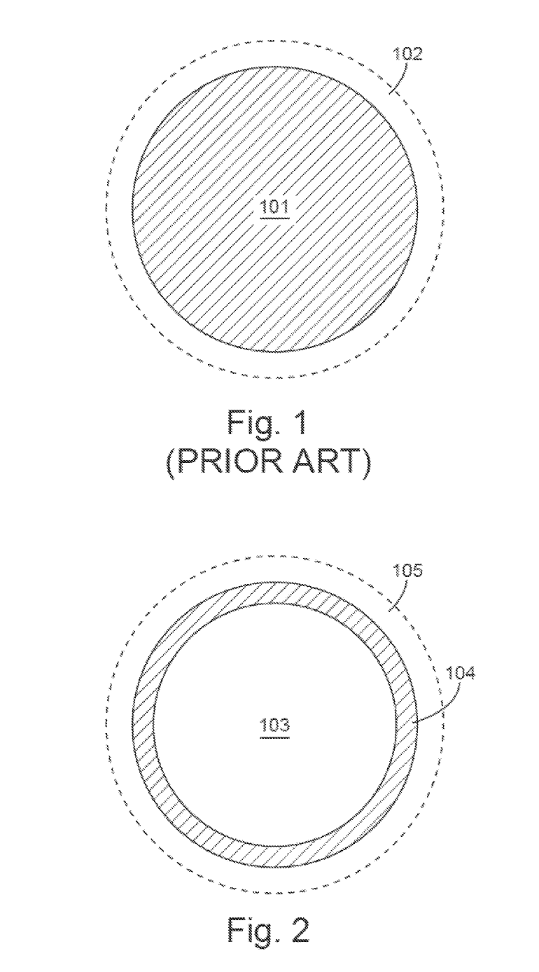

FIG. 1 illustrates generally an existing silicon dioxide (SiO2) filler material 101 and polymer-filler interaction zone 102. Silicon dioxide (silica or quartz) has a bulk modulus (K), CTE, and Young's modulus (E) of: 1.3 W/mK; 12.3/0.4 ppm/K; and 70 GPa. Conventional filler materials, such as silicon dioxide, are typically used due to the polar nature of their surface, leading to better adhesion with polymer resin.

Silicon nanofillers having a modulus greater than conventional filler material (e.g., a 200 nanometer silicon nanofiller has a modulus on the order of 2× conventional silicon dioxide filler material, and no CTE compromise). However, silicon nanofillers have not been used as fillers in microelectronics materials due to their poor adhesion with polymer resin. The present inventors have recognized, however, that an outer layer of the silicon nanofiller can be thermally oxidized to form a shallow, outer layer of silica, for example, having a thickness between 1 and 10 nanometers, between 10 and 20 nanometers, or between 1 and 20 nanometers. The thermally oxidized shallow, outer layer of silica can interact with a polymer resin similar to conventional silica filler material, keeping processing of the composite, polymer material virtually unchanged, as the interface is still a metal-oxide, while reducing warpage and greatly increasing stiffness at high temperatures.

In other examples, silicon carbide (SiC) nanofillers can be used, having a modulus of 400 GPa, 5 times greater than silicon dioxide filler material, and having advantageous dielectric properties for low dielectric constant (Dk), dissipation factor (Df) packages.

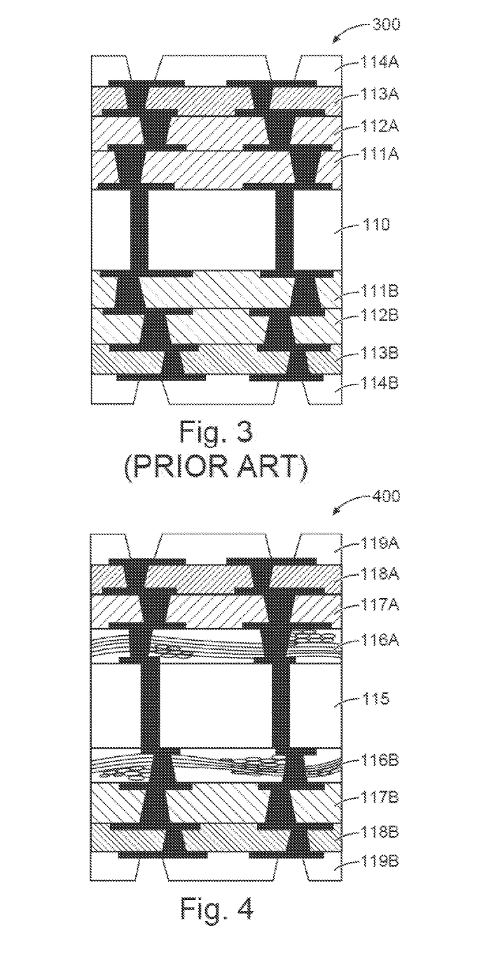

FIG. 2 illustrates generally an example modified filler material having a modulus greater than a core material composed of silicon dioxide alone, and an adhesion, such as a surface adhesion, greater than silicon (Si) or silicon carbide (SiC) alone. The example modified filler material can include a nanofiller core material 103, an outer layer 104 of oxidized nanofiller core material surrounding the nanofiller core material 103, and a polymer-filler interaction zone 105. The nanofiller core material 103 can include silicon (Si), silicon carbide (SiC), or one or more other nanofiller core material that can be thermally oxidized.

In an example, the outer layer 104 is thermally oxidized nanofiller core material 103, providing greater adhesion in contrast to a layer of oxide grown on the outside of a nanofiller core material 103. The outer layer 104 of oxidized nanofiller core material can include silicon dioxide having a thickness between 1 and 10 nanometers, between 10 and 20 nanometers, or between 1 and 20 nanometers, created using the nanofiller core material 103 itself. By carefully controlling the percent of oxidation of the nanofiller core material 103, the modified filler material can be formed. In an example, the oxidation can be described by the following stoichiometric equation:

2SiC+3O2→2SiO2+2CO

A plurality of modified filler material can be embedded in one or more polymer materials, such as core material, build-up (BU) material, pre-impregnated composite fibers (pre-preg) material, underfill material, mold material, adhesives, interface material, or any other polymeric or dielectric material to provide a high modulus at all temperatures.

In an example, an outer layer of a nanofiller core material, having a modulus greater than a core material composed of silicon dioxide (SiO2) alone, can be oxidized, creating a silicon dioxide layer on the nanofiller core material (e.g., using the nanofiller core material in the oxidizing process) to increase adhesion of the outer layer to a composite resin in contrast to adhesion of the nanofiller core material to the composite resin. In an example, a plurality of the composite nanofillers can be added to a composite resin to form a stress-tolerant composite material having an increased stiffness in comparison to a composite material formed from the composite resin alone, without the plurality of composite nanofillers.

The present inventors have recognized, among other things, a hybrid architecture to control dynamic package warpage, combining effects of increased substrate stiffness, lowered high temperature (HT) CTE, and increased glass transition temperature (Tg), with almost zero height increase in the overall thickness. In an example, the hybrid architecture can include a first layer pair 1-2F (front), 1-2B (back) with pre-impregnated composite fiber (pre-preg, PP) material instead of typical build-up (BU) material to increase overall stiffness and lower CTE.

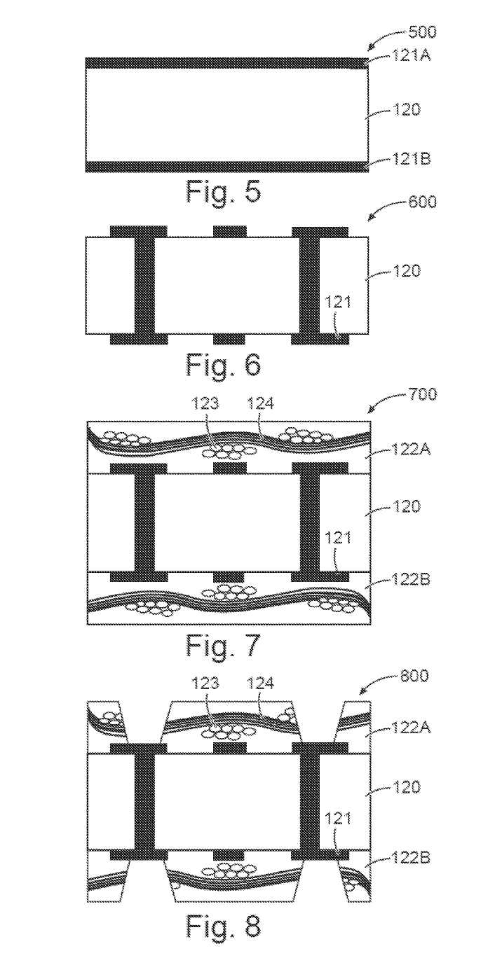

FIG. 3 illustrates generally a conventional substrate architecture 300 including a core material 110, a first build-up (BU) material 111A, 111B, a second BU material 112A, 112B, a solder resist (SR) material 113A, 113B, and one or more conductors (black) through or between one or more of the layers, above.

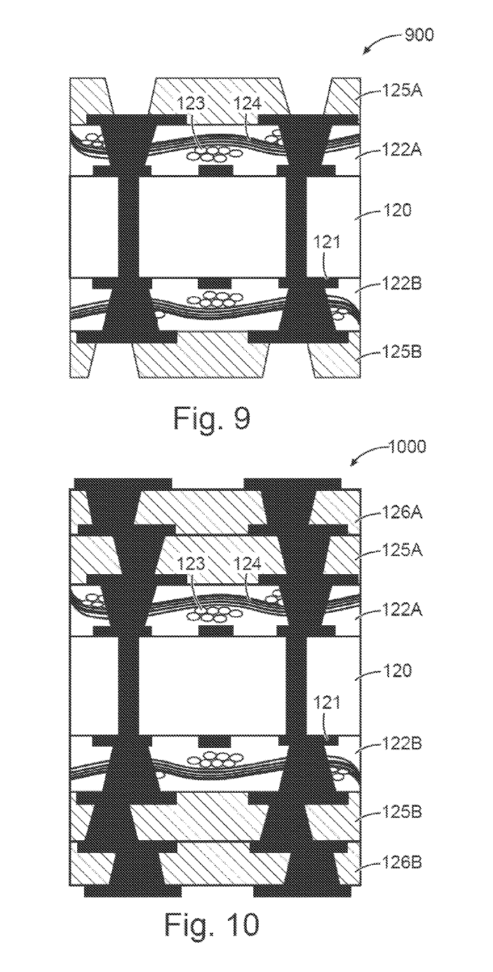

FIG. 4 illustrates generally a cross section of an example hybrid architecture 400 including a core material 115, and a pre-impregnated composite fiber (pre-preg, PP) material 116A, 116B on the core material 115. In certain examples, the PP material 116A, 116B can include one or more different materials (e.g., PP E679FGR, PP R1410, etc.) in combination with the modified filler material (circles in the PP material 116A, 116B) disclosed herein, and can optionally include glass weaves (wavy lines across the PP material 116A, 116B) or other reinforcement or fabric-like composite fiber material to further increase stiffness of the PP material.

The example hybrid architecture 400 includes a first BU material 117A, 117B on the PP material 116A, 116B, a second BU material 118A, 118B on the first BU material 117A, 117B, and a SR material 119A, 119B on the second BU material 118A, 118B, respectively, and one or more conductors (black) through or between one or more of the layers.

In an example, one or more of the core material 115, the first and second BU material 117A, 117B, 118A, 118B, the SR material 119A, 119B, or one or more other materials in the example hybrid architecture 400 can include modified filler material or composite fiber, such as described above with respect to the PP material 116A, 116B, for example, to improve stiffness, lower CTE, and decrease warpage of the materials across all temperature ranges. In certain examples, the hybrid architecture can be used to scale up input/output (IO) density and increase die to package ratios without sacrificing, and in certain examples improving, functionality.

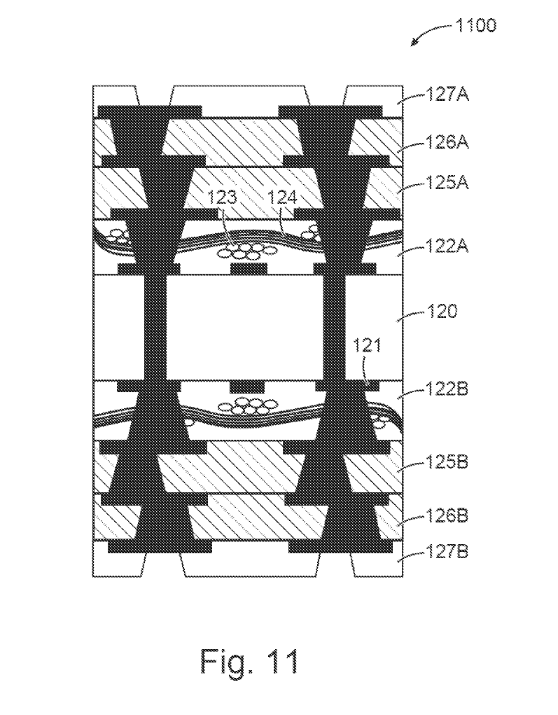

FIGS. 5-11 illustrate generally example cross sections of a process flow for a hybrid architecture, such as that disclosed in FIG. 4, above. FIG. 5 illustrates generally an example cross section 500 of an incoming core panel including a core material 120 having a top surface and a bottom surface, and first and second conductive plates 121A, 121B (e.g., copper) disposed (e.g., laminated, etc.) on the top and bottom surfaces of the core material 120. In an example, a portion of the first and second conductive plates 121A, 121B, or the core material 120, can be removed (e.g., patterned and etched, laser etched, drilled, etc.), depending on the desired configuration.

FIG. 6 illustrates generally an example cross section 600 including the core material 120 having one or more conductors formed therethrough, such as the first conductor 121. FIG. 7 illustrates generally an example cross section 700 including a PP material 122A, 122B disposed on the top and bottom surfaces of the core material 120, respectively. The PP material 122A, 122B can include modified filler material, such as a first modified filler 123, and composite fiber material 124. In an example, a portion of the PP material 122A, 122B can be removed (e.g., patterned and etched, laser etched, drilled, etc.), depending on the desired configuration.

FIG. 8 illustrates generally an example cross section 800 including removed portions of the PP material 122A, 122B. FIG. 9 illustrates generally an example cross section 900 including one or more conductors deposited through and on the PP material 122A, 122B (e.g., electroplated, etc.), depending on the desired configuration, and a first BU material 125A, 125B disposed on a top surface of the PP material 122A, 122B.

FIG. 10 illustrates generally an example cross section 1000 including additional conductors, such as illustrated in black and depending on the desired configuration, and a second BU material 126A, 126B disposed (e.g., laminated) on the first BU material 125A, 125B from FIG. 9. FIG. 11 illustrates generally an example cross section 1100 including first and second solder resist (SR) material 127A, 127B disposed (e.g., laminated) on the additional BU material. The first and second SR material 127A, 127B can be patterned and etched to expose one or more conductive pads, such as those in FIG. 11 coupled to the first conductor 121.

In an example, one or more of the core material 120, the first BU material 125A, the additional BU material, the SR material 127A, 127B, or one or more other materials in the example hybrid architecture can include modified filler material or composite fiber, such as described above with respect to the PP material 122A, 122B, for example, to improve stiffness, lower CTE, and decrease warpage of the materials across all temperature ranges.

In certain examples, the hybrid architecture disclosed herein is not limited to a cored substrate, but can instead be visualized as an example of minimizing the Z-height by making a hybrid coreless structure including PP and BU material only.

### Additional Notes and Examples

In Example 1, a microelectronic material system includes: a composite nanofiller, including: a nanofiller core material having a modulus greater than a core material composed of silicon dioxide (SiO2) alone; and an outer layer of oxidized nanofiller core material surrounding the nanofiller core material.

In Example 2, the subject matter of Example 1 optionally includes, wherein the outer layer is thermally oxidized nanofiller core material.

In Example 3, the subject matter of Example 2 optionally includes, wherein the outer layer includes silicon dioxide and has a thickness range between 1 and 10 nanometers.

In Example 4, the subject matter of any one or more of Examples 1-3 optionally include, wherein the nanofiller core material has a modulus greater than a core material composed of: magnesium peroxide (MgO2), aluminum oxide (Al2O3), or calcium carbonate (CaCO3), and wherein the composite nanofiller has an adhesion higher than silicon (Si) or silicon carbide (SiC).

In Example 5, the subject matter of any one or more of Examples 1-4 optionally include, wherein the nanofiller core material is silicon carbide (SiC).

In Example 6, the subject matter of any one or more of Examples 1-5 optionally include, wherein the nanofiller core material is silicon (Si).

In Example 7, the subject matter of any one or more of Examples 1-6 optionally include, including a composite material having a plurality of composite nanofillers, wherein the composite nanofillers are configured to increase the stiffness of the composite material in contrast to a composite material not having the plurality of composite nanofillers.

In Example 8, the subject matter of Example 7 optionally includes, wherein the composite material is composed of a resin, reinforcement fibers, and the plurality of nanofillers, and wherein the outer layer of oxidized nanofiller core material is configured to increase adhesion of the composite nanofiller to the composite resin in contrast to adhesion of the nanofiller core material to the composite resin.

In Example 9, a microelectronic material processing method includes: oxidizing an outer layer of a nanofiller core material to increase adhesion of the outer layer to a composite resin in contrast to adhesion of the nanofiller core material to the composite resin, wherein the nanofiller core material has a modulus greater than a core material composed of silicon dioxide (SiO2) alone.

In Example 10, the subject matter of Example 9 optionally includes, wherein oxidizing the outer layer of the nanofiller core material creates a silicon dioxide layer on the nanofiller core material.

In Example 11, the subject matter of Example 10 optionally includes, wherein oxidizing the outer layer of a nanofiller core material includes thermally oxidizing a silicon dioxide layer using the nanofiller core material, and wherein the silicon dioxide layer has a thickness between 1 and 10 nanometers.

In Example 12, the subject matter of any one or more of Examples 9-11 optionally include, wherein the nanofiller core material has a modulus greater than a core material composed of: magnesium peroxide (MgO2), aluminum oxide (Al2O3), or calcium carbonate (CaCO3).

In Example 13, the subject matter of any one or more of Examples 9-12 optionally include, wherein the nanofiller core material is silicon carbide (SiC).

In Example 14, the subject matter of any one or more of Examples 9-13 optionally include, wherein the nanofiller core material is silicon (Si).

In Example 15, the subject matter of any one or more of Examples 9-14 optionally include, including adding a plurality of the composite nanofillers to a composite resin to form a stress-tolerant composite material having an increased stiffness in comparison to a composite material formed from the composite resin alone, without the plurality of composite nanofillers.

In Example 16, a method of providing a stress-tolerant composite material includes: adding a composite nanofiller to a composite resin, the composite nanofiller including: a nanofiller core material having a modulus greater than a core material composed of silicon dioxide (SiO2) alone; and an outer layer of oxidized nanofiller core material surrounding the nanofiller core material.

In Example 17, the subject matter of Example 16 optionally includes, including: thermally oxidizing an outer layer of the nanofiller core material, prior to adding the composite nanofiller to the composite resin, to increase adhesion of the outer layer to a composite resin in contrast to adhesion of the nanofiller core material to the composite resin.

In Example 18, the subject matter of Example 17 optionally includes, wherein the outer layer of oxidized nanofiller core material includes silicon dioxide and has a thickness between 1 and 10 nanometers.

In Example 19, the subject matter of any one or more of Examples 16-18 optionally include, wherein the nanofiller core material has a modulus greater than a core material composed of: magnesium peroxide (MgO2), aluminum oxide (Al2O3), or calcium carbonate (CaCO3), and wherein the composite nanofiller has an adhesion higher than silicon (Si) or silicon carbide (SiC).

In Example 20, the subject matter of any one or more of Examples 16-19 optionally include, wherein the nanofiller core material is silicon carbide (SiC) or silicon (Si).

In Example 21, a composite architecture can include: core material having a top surface; pre-preg (PP) material disposed on the top surface of the core material, the PP material having a top surface, a bottom surface, and composite fiber therein; a first build-up (BU) material disposed on the top surface of the PP material, the first BU material having a top surface and a bottom surface; a second BU material disposed on the top surface of the first BU material, the second BU material having a top surface and a bottom surface; and solder resist (SR) material disposed on the top surface of the second BU material, the SR material having a top surface and a bottom surface; and at least one conductor making an electrical connection between at least two of the core, PP, first or second BU, or SR materials.

In Example 22, the subject matter of Example 1 optionally includes, wherein the core material includes composite fiber therein.

In Example 23, the subject matter of any one or more of Examples 21-22 optionally include: second PP material disposed on the bottom surface of the core material, the second PP material having a top surface, a bottom surface, and composite fiber therein; third BU material disposed on the top surface of the second PP material, the second BU material having a top surface and a bottom surface; fourth BU material disposed on the top surface of the third BU material, the fourth BU material having a top surface and a bottom surface; and second SR material disposed on the top surface of the fourth BU material, the second SR material having a top surface and a bottom surface.

In Example 24, a system or apparatus can include, or can optionally be combined with any portion or combination of any portions of any one or more of Examples 1-23 to include, means for performing any one or more of the functions of Examples 1-23, or a machine-readable medium including instructions that, when performed by a machine, cause the machine to perform any one or more of the functions of Examples 1-23.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronic material system, comprising:
a composite nanofiller, including:
a nanofiller core material having a modulus greater than a core material composed of silicon dioxide (SiO2) alone; and
an outer layer of oxidized nanofiller core material surrounding the nanofiller core material.

2. The system of claim 1, wherein the outer layer is thermally oxidized nanofiller core material.

3. The system of claim 2, wherein the outer layer includes silicon dioxide and has a thickness range between 1 and 10 nanometers.

4. The system of claim 1, wherein the nanofiller core material has a modulus greater than a core material composed of: magnesium peroxide (MgO2), aluminum oxide (Al2O3), or calcium carbonate (CaCO3), and
wherein the composite nanofiller has an adhesion higher than silicon (Si) or silicon carbide (SiC).

5. The system of claim 1, wherein the nanofiller core material is silicon carbide (SiC).

6. The system of claim 1, wherein the nanofiller core material is silicon (Si).

7. The system of claim 1, including a composite material having a plurality of composite nanofillers,
wherein the composite nanofillers are configured to increase the stiffness of the composite material in contrast to a composite material not having the plurality of composite nanofillers.

8. The system of claim 7, wherein the composite material is composed of a resin, reinforcement fibers, and the plurality of nanofillers, and
wherein the outer layer of oxidized nanofiller core material is configured to increase adhesion of the composite nanofiller to the composite resin in contrast to adhesion of the nanofiller core material to the composite resin.

9. A microelectronic material processing method, comprising:
oxidizing an outer layer of a nanofiller core material to increase adhesion of the outer layer to a composite resin in contrast to adhesion of the nanofiller core material to the composite resin,
wherein the nanofiller core material has a modulus greater than a core material composed of silicon dioxide (SiO2) alone.

10. The method of claim 9, wherein oxidizing the outer layer of the nanofiller core material creates a silicon dioxide layer on the nanofiller core material.

11. The method of claim 10, wherein oxidizing the outer layer of a nanofiller core material includes thermally oxidizing a silicon dioxide layer using the nanofiller core material, and
wherein the silicon dioxide layer has a thickness between 1 and 10 nanometers.

12. The method of claim 9, wherein the nanofiller core material has a modulus greater than a core material composed of: magnesium peroxide (MgO2), aluminum oxide (Al2O3), or calcium carbonate (CaCO3).

13. The method of claim 9, wherein the nanofiller core material is silicon carbide (SiC).

14. The method of claim 9, wherein the nanofiller core material is silicon (Si).

15. The method of claim 9, including adding a plurality of the composite nanofillers to a composite resin to form a stress-tolerant composite material having an increased stiffness in comparison to a composite material formed from the composite resin alone, without the plurality of composite nanofillers.

16. A method of providing a stress-tolerant composite material, comprising:
adding a composite nanofiller to a composite resin, the composite nanofiller including:
a nanofiller core material having a modulus greater than a core material composed of silicon dioxide (SiO2) alone; and
an outer layer of oxidized nanofiller core material surrounding the nanofiller core material.

17. The method of claim 16, including:
thermally oxidizing an outer layer of the nanofiller core material, prior to adding the composite nanofiller to the composite resin, to increase adhesion of the outer layer to a composite resin in contrast to adhesion of the nanofiller core material to the composite resin.

18. The method of claim 17, wherein the outer layer of oxidized nanofiller core material includes silicon dioxide and has a thickness between 1 and 10 nanometers.

19. The method of claim 16, wherein the nanofiller core material has a modulus greater than a core material composed of: magnesium peroxide (MgO2), aluminum oxide (Al2O3), or calcium carbonate (CaCO3), and
wherein the composite nanofiller has an adhesion higher than silicon (Si) or silicon carbide (SiC).

20. The method of claim 16, wherein the nanofiller core material is silicon carbide (SiC) or silicon (Si).
